(19) United States
(12) Patent Application Publication
(10) Pub. No.: US 2018/0100944 A1
(43) Pub. Date: Apr. 12, 2018

(54) METHOD FOR DETERMINING A RELATIVE DIELECTRIC CONSTANT AND DETECTION METHOD FOR GROUND EMBEDDED OBJECTS

(71) Applicant: Vallon GmbH, Eningen (DE)

(72) Inventors: Jan Fahlbusch, Braunschweig (DE); Armin Merz, Eningen (DE)

(21) Appl. No.: 15/687,766

(22) Filed: Aug. 28, 2017

(30) Foreign Application Priority Data
Oct. 11, 2016 (EP) 16193182.9

(51) Int. Cl. G01V 3/12; G01S 13/04; G01S 13/08; G01R 27/26

(52) U.S. Cl. CPC G01V 3/12; G01S 13/04; G01V 3/38; G01R 27/2617; G01S 13/08

(57) ABSTRACT

A method for determining a relative dielectric constant of a ground to be searched for mines using a detector including at least one detection coil and a ground penetrating radar including at least one transmitter antenna and at least one receiver antenna and a detection method for detecting metal and non-metal objects in a ground using a mine detector including a metal detector and a ground penetrating radar, wherein the metal detector includes at least one detection coil with a coil plane which is moved parallel to the ground during detecting, and wherein the ground penetrating radar includes an antenna arrangement including at least one transmitter antenna and at least one receiver antenna. The method according to the invention for determining a relative dielectric constant enables a user to calibrate the detector quickly and in a known manner with respect to ground properties of the ground to be searched.

### RELATED APPLICATIONS

This application claims priority from and incorporates by reference European Patent Application EP 16 193 182 9 filed on Oct. 11, 2016 which is incorporated in its entirety by this reference.

### FIELD OF THE INVENTION

The invention relates to a method for determining a relative dielectric constant ε_{R} of a ground that is to be searched for metal and non-metal objects using a detector including at least one ground penetrating radar including at least one transmitter antenna and at least one receiver antenna and a detection method for finding mines in the ground using a mine detector including a metal detector and a ground penetrating radar, wherein the metal detector includes at least one detection coil with a coil plane which moves parallel to the ground for searching and wherein the ground penetrating radar is provided with an antenna arrangement including at least one transmitter antenna and a receiver antenna.

### BACKGROUND OF THE INVENTION

When searching for objects in the ground, in particular mines, it is desirable to be able to define and estimate at least an approximate depth of an object in the ground in addition to a position of the object below the surface. The problem is that in order to determine depth which is typically done with known devices ground properties have to be known. Search equipment which is used for this purpose is essentially equipment with a ground penetrating radar or combination equipment which includes an additional metal detector.

The combination equipment is configured to find metal and non-metal objects in the ground which also includes mines without metal components. Ground penetrating radar (GPR) is a device which facilitates nondestructive characterization of the ground with electromagnetic waves with frequencies in the radar range.

Basically there are two principles according to which either a distance is determined from a time differential between transmitting a transmission impulse by a transmitter antenna and receiving the reflected signals at a receiver antenna or a differential frequency or differential phase is computed between the transmission and receiving signal. As a matter of principle a band width of the transmission signal is desired that is as big as possible in order to achieve an optimum result with respect to penetration depth into the ground and resolution of the structures (mines, etc.) to be detected. As a matter of principle the antennas can be one of the known variants of planar dipole antennas (linear or gradually expanding dipole antenna, bow tie antenna, dipole with V-shaped arms, dipole with circular, elliptical or tear drop shaped arms, etc.) which are made from a non-conductive material, for example a plastic material and which are only metalized at their two arms. A ground penetrating radar is suitable in particular when the objects contain so little metal that it is difficult for a metal detector to find the metal. However, since the dielectric contrast for example between a mine and the ground can be rather large devices with ground penetrating radar can be advantageous for this application.

Since the ground penetrating radar emits electro-magnetic waves in a known manner through a transmission antenna configured as a dipole a run time of the reflected signal which is received by a receiver antenna is a function of the relative dielectric constant ε_{R}. The run time can be computed according to the equation ε_{R} (cₒ/c)² wherein cₒ is the transmission speed in air or in vacuum and c is the transmission in the ground, Thus, when ε_{R} is known a depth of an object in the ground can be determined from a run time of a signal being transmitted into the ground and being received again. The relative dielectric constant ε_{R} is determined by structural characteristics of a ground material (gravel, sand, mix, etc.) and by its radar illumination. Compared to dry ground the run times for a humid ground and by the same token also an attenuation of the signal running through the ground are significantly greater.

The process for determining the relative dielectric constant ε_{R} is performed so that reference objects are buried at two different depths in an area with a ground composition that corresponds to the area to be searched. Both reference objects are detected by ground radar and computing the relative dielectric constant ε_{R} is performed based on the difference of the measured run time and the known depths in the ground. Thereafter the sensor is manually adjusted with respect to measuring frequency range and amplification so that both objects can be detected easily.

### BRIEF SUMMARY OF THE INVENTION

Thus, it is an object of the instant invention to provide an improved method to determine the a relative dielectric constant ε^{R} so that the method can be used directly in a subsequent detection process for finding particular mines in the ground in order to sufficiently estimate a depth of an object in the ground.

The object is achieved according to the invention by a method for determining a relative dielectric constant of a ground to be searched for metal and non-metal objects, the method including the steps using a detector including at least one detection coil and a ground penetrating radar including at least one transmitter antenna and at least one receiver antenna; performing measurements of a characteristic section of the ground to be searched by the detector emitting a transmission signal through the at least one transmitter antenna and receiving a reception signal through the at least one receiver antenna and measuring an elapsed time between emitting the transmission signal and receiving the reception signal in a first position with the detector oriented away from the ground with a side of the detector that is active for the search; and in a second position with the detector contacting the ground with the side of the detector that is active for the search; determining a first mean signal velocity from a signal run time through air and through a direct signal path in the detector between the transmitter antenna and the receiver antenna in the first position; determining a second mean signal velocity from the signal run time between the transmitter antenna and the receiver antenna at least through the ground and through the direct signal path in the detector in the second position; and determining a relative dielectric constant from a ratio of the first mean sign velocity and the second mean signal velocity.

The object is also achieved by a detection method for detecting metal and non-metal objects in a ground, the method including the steps using a mine detector including a metal detector and a ground penetrating radar, wherein the metal detector includes at least one detection coil with a coil plane which is moved parallel to the ground during detecting, and wherein the ground penetrating radar includes an antenna arrangement including at least one transmitter antenna and at least one receiver antenna; initially performing measurements for determining the relative dielectric constant described supra for a characteristic section of the around to be searched; associating the relative dielectric constant with a defined measuring frequency range in view of the frequency driven attenuation and determining a maximum frequency driven and ground driven measuring depth and displaying the maximum frequency driven and ground driven measuring depth by a display device; and performing measurements to find mines in the ground wherein the measurements are performed along a path above the ground to be searched; using simultaneous transmission of signals from the detection coil and the at least one transmitter antenna and receiving impulses transmitted by the detection coil and signals emitted by the at least one transmitter antenna and received by the at least one receiver antenna to generate a ground profile from which a size and a position in space of an object arranged in the ground is determined.

### DETAILED DESCRIPTION OF THE INVENTION

According to the invention the method for determining the relative dielectric constant ε_{R} is performed so that initially a representative section of the ground to be tested is selected e.g. at an edge of the area to be searched. Using a detector with at least one ground radar a transmission signal is transmitted by the at least one transmission antenna and the received signal is received by the at least one receiver antenna and the time between transmission and reception is determined.

The measurements are performed when a) the detector is an oriented away from the ground with its active search side and b) when the detector contacts the ground. The measurement a) is performed in order to obtain a reproducible comparison value for the propagation velocity of the signal in the air for the subsequent determination of the relative dielectric constant ε_{R} and in case b) a measuring value for the propagation velocity of the signal in the ground. Thus for the measurement a) a measurement is performed in air wherein it is important that there are no objects in a direct vicinity of the antennas, wherein the objects could disturb the comparison measurement. For the measurement b) a portion at an edge of an area to be searched can be used as a reference portion wherein the portion should have ground properties that are identical with the area to be searched wherein the detector is placed onto the reference portion. It may be necessary to remove vegetation from the reference portion since vegetation also incudes water and influences the measurement additionally.

Next a mean signal velocity is determined from the signal run time through the air and the direct signal path in the detector between the transmitter antenna and the receiver antenna in the position a). Thus a major portion of the signal runs directly between the transmitter antenna and the receiver antenna wherein the remaining signal portions decrease through the air with a distance from the direct travel path. When the transmitter antenna and the receiver antenna are jointly arranged on a circuit board there is a cross coupling on a direct path between the two antennas through the printed circuit board. The received signal is an additive mix of all signal portions with respect to its signal form wherein the received signal is reduced, broadened and time shifted with respect to its amplitude compared to the transmitted signal.

Accordingly a mean signal velocity is determined from the signal run time between the transmitter antenna and the receiver antenna through the ground and through the air and through the direct signal path in the detector in position b), wherein also here the received signal is a superposition all signal portions with respect to its signal form wherein the received signal is reduced in amplitude, broadened and time shifted relative to the transmitted signal. The reduction is performed through the signal decrease with distance and attenuation, the broadening is performed by the different velocities. The essential portion is the signal that is over coupled on the direct path between the two antennas.

The relative dielectric constant ε_{R} is then determined from the ratio of the two mean signal velocities according to the measurements a) and b). This is possible because only the differences from a) that are determined from the measurement b) are relevant since results of the measurement a) are compared with results of the measurements b). According to this method the ground is measured with a type of open structure and the effect of the ground upon the open structure is determined. This structure is open in a form so that it generates electromagnetic waves through an electrical field that penetrates the ground and whose return is measured. As stated supra the cross coupling between both antennas includes several components which run very close to the printed circuit board and which have a certain extension into the ground and into the air. Through both measurements a) and b) the ratios of the components of the cross coupling change. It is possible that the cross coupling is delayed. As a matter of principle the transmission is performed in the so called near field of the antenna. The near field is a distance range that is comparable to the wave length of the signal. In the near field the phenomenon can be explained solely by propagation of the potential fields. In the remote field a radiation theory explanation suffices. During the processing a signal portion which is always provided, namely the signal measured by direct cross coupling of the antennas is being used. This can be a coupling through the near field of the antenna or by a surface wave which moves along in the structure of the printed circuit board. In any case portions which run in a very concentrated manner between the two antennas and which also expand slightly into a space in the ground are processable with typical signal measuring methods like e.g. curve fitting by a Gauss function, setting of filters or windows. This, however cannot be separated precisely. It was found that the cross coupling changes in a reproducible manner compared to a measurement in air when the ground properties change, namely as stated supra by changing the time based position of the maximum, the amplitude of the maximum and the width of the curve.

As stated supra the antennas can be arranged on carrier, typically on a printed circuit board. Since the antennas shall primarily transmit electromagnetic waves into the ground they are configured accordingly with their effective surface. When signal portions arrive at the receiver antenna which have propagated through the air on the operating surface in opposite direction, in the embodiment of a circuit board through the air on aside of the circuit board that is oriented away from the ground, these portions are provided for both measurements a) and b). According to a particularly advantageous embodiment of the invention at least the electromagnetic waves reaching the ground penetrating radar from the atmosphere and the electromagnetic waves that are emitted by the ground penetrating radar in a direction that is opposite to the ground are shielded by absorber elements and the mean signal velocity is determined from the signal run time between the transmitter antenna and the receiver antenna through the ground and the direct signal path in the detector in the position b). This processing is more precise since signal portions that are propagated through the air are substantially processed by half in the measurement a) and suppressed substantially completely in the measurement b). Determining the dielectric constant is performed by a control and computation unit that is integrated in the detector. A use of absorber elements in a ground penetrating radar is a typical measure, wherein cavities in the absorber elements are created in a known manner in order to attenuate the emitted waves. The cavities are defined at their outer surfaces by a material absorbing electromagnetic waves (e.g. foam absorber or rubber absorber or absorber lacquer) and/or reflecting material, e.g. metal. Thus, the at least one receiver antenna does not receive signals either which impact the ground penetrating radar from the atmosphere.

The method described supra can thus be used for determining the relative dielectric constant for the ground of the area to be searched. If the user detects a change of the ground during the detection process a new determination of the changed dielectric constant is required for the area with the changed ground according to the method described supra. Thus, the relative dielectric constant for the area to be searched can be determined in a simple and quick manner and changes in the ground can be addressed.

The detection according to the detection method according to the invention can be performed with the determined relative dielectric constant for the area to be searched. This is performed by using a mine detector with a metal detector and a ground penetrating radar wherein the metal detector includes at least one detection coil with a coil plane which is moved parallel to the ground during searching and the ground penetrating radar is provided with an antenna arrangement with at least one transmitter antenna and a receiver antenna, wherein measurements are performed initially for a section of the ground that is exemplary for the ground to be searched in order to determine a relative dielectric constant as described supra. After the relative dielectric constant is determined the measurement frequency range can be associated therefrom in view of the frequency driven damping and the maximum frequency dependent and ground dependent measuring depth can be determined and advantageously displayed by a corresponding display device.

As stated supra the attenuation of the electromagnetic waves transmitted into the ground increases also as a function of frequency with an increasing relative dielectric constant. Thus it is required to optically indicate to the user at which threshold frequency and at which amplification the user can detect which maximum depth.

Subsequently measurements for finding mines arranged in the ground are performed along a path to be searched above the ground to be searched. Thus simultaneous transmission of signals from the detection coil and the at least one transmitter antenna and receiving the impulses emitted by the detection coil and signals emitted by the at least one transmitter antenna through the at least one receiver antenna is used to generate a ground profile in a typical manner by a control and computation unit arranged in the detector. From the ground profile a size and a depth of an object arranged in the ground is determined and an optical and/or acoustic signal is emitted when identifying an object that is detected in the ground. The movement of the detector close to the ground corresponds to the typical mine search where the detector is moved over the ground as close as possible to the ground without touching the ground. The signals received during measurement along the ground are processed by the typical and known signal processing and signal evaluation methods by generating a colored depth value profile from the individual time based signals received over the detection path wherein the value profile is hyperbolic when defined three dimensional plane objects are arranged in the ground so that a depth and a size of the object can be determined therefrom. An apex point of the respective hyperbola defines a depth and a spread of the hyperbola defines an approximate shape and size of the object. Advantageously these can be put out as an acoustic signal to indicate presence of an object at a particular location and a graphic representation on a display device configured as a display. Advantageously a transmission frequency between 400 MHz and 3 GHz is used for the ground penetrating radar.

The method according to the invention to determine a relative dielectric constant ε_{R} enables the user to calibrate the detector quickly and in a known manner with respect to the ground properties of the area to be searched. Through the detection method according to the invention which is based on the determined relative dielectric constant essential data that is required for the search and the detection is provided to the user of the detector. Thus, handling the detector is simplified considerably for the user since it is demonstrated to the user after the dielectric constant is determined how the user has to adjust the threshold frequency for the measurement and also for the amplification based on the attenuation of the electromagnetic waves in the ground in order to be able to detect objects at a depth that is desired by the user. Thus it is indicated to the user which maximum depth can be detected based on the determined dielectric constant.

What is claimed is:

1. A method for determining a relative dielectric constant of a ground to be searched for metal and non-metal objects; the method comprising the steps:
using a detector including at least one detection coil and a ground penetrating radar including at least one transmitter antenna and at least one receiver antenna;
performing measurements of a characteristic section of the ground to be searched by the detector emitting a transmission signal through the at least one transmitter antenna and receiving a reception signal through the at least one receiver antenna and measuring an elapsed time between emitting the transmission signal and receiving the reception signal
in a first position with the detector oriented away from the ground with a side of the detector that is active for the search, and
in a second position with the detector contacting the ground with the side of the detector that is active for the search;
determining a first mean signal velocity from a signal run time through air and through a direct signal path in the detector between the transmitter antenna and the receiver antenna in the first position;
determining a second mean signal velocity from the signal run time between the transmitter antenna and the receiver antenna at least through the ground and through the direct signal path in the detector in the second position; and
determining a relative dielectric constant from a ratio of the first mean sign velocity and the second mean signal velocity.

2. The method according to claim 1,
wherein at least electromagnetic waves impacting the ground penetrating radar from an atmosphere and electromagnetic waves emitted by the ground penetrating radar in a direction opposite to the ground are shielded by absorber elements and
wherein a mean signal velocity is determined from a signal run time between the transmitter antenna and the receiver antenna through the ground and a direct signal path in the detector in the second position.

3. A detection method for detecting metal and non-metal objects in a ground, the method comprising the steps:
using a mine detector including metal detector and a ground penetrating radar,
wherein the metal detector includes at least one detection coil with a coil plane which is moved parallel to the ground during detecting, and
wherein the ground penetrating radar includes an antenna arrangement including at least one transmitter antenna and at least one receiver antenna;
initially performing measurements for determining the relative dielectric constant according to claim 1 for a characteristic section of the ground to be searched;
associating the relative dielectric constant with a defined measuring frequency range in view of the frequency driven attenuation and determining a maximum frequency driven and ground driven measuring depth and displaying the maximum frequency driven and ground driven measuring depth by a display device; and
performing measurements to find mines in the ground wherein the measurements are performed along a path above the ground to be searched;
using simultaneous transmission of signals from the detection coil and the at least one transmitter antenna and receiving impulses transmitted by the detection coil and signals emitted by the at least one transmitter antenna and received by the at least one receiver antenna to generate a ground profile from which a size and a position in space of an object arranged in the ground is determined.

4. The detection method according to claim 3, wherein an approximate depth of the detected object is determined and displayed.

5. The detection method according to claim 3, wherein an approximate size of the detected object is determined and displayed.

6. The detection method according to claim 3, wherein a transmission frequency between 400 MHz and 3 GHz is used for the ground penetrating radar.
